(19) United States
(12) Patent Application Publication
(10) Pub. No.: US 2007/0231940 A1
(43) Pub. Date: Oct. 4, 2007

(54) Composition and method of dyeing keratin fibers comprising luminescent semiconductive nanoparticles

(75) Inventors: Luc Gourlaouen, Asnieres (FR); Kenneth Lee, Paris (FR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: L'OREAL S.A.

(21) Appl. No.: 11/806,306

(22) Filed: May 31, 2007

Related U.S. Application Data
(63) Continuation of application No. 10/764,436, filed on Jan. 27, 2004, now abandoned.

(30) Foreign Application Priority Data
Jan. 27, 2003 (FR) 03 00860

(51) Int. Cl. H01L 21/00; A61Q 5/10

(52) U.S. Cl. 438/22; 8/405; 977/926

(57) ABSTRACT

Composition and method for dyeing keratin materials, such as hair, comprising luminescent semiconductive nanoparticles capable of emitting, under the action of a light excitation, radiation with a wavelength ranging from 400 nm to 700 nm.

This application claims benefit of U.S. Provisional Application No. 60/450,698, filed Mar. 3, 2003, which is herein incorporated by reference.

Disclosed herein is a cosmetic method for dyeing keratin fibers comprising, in a composition, luminescent semiconductive nanoparticles, such as nanoparticles comprising cadmium sulphide or cadmium selenide, capable of emitting, under the action of a light excitation, radiation with a wavelength ranging from 400 nm to 700 nm.

In the field of the dyeing of keratin fibers, for example, human keratin fibers, such as hair, two modes of dyeing exist, which each have their advantages and drawbacks:
direct dyeing or semi-permanent dyeing consists in introducing the color via a colored molecule, which is adsorbed onto the surface of the keratin fibers and/or penetrates by diffusion into the surface layers of these fibers. The leave-in times are generally fairly short and the mild dyeing conditions preserve the integrity of the keratin fibers, but the colorations obtained by this mode of dyeing may show poor wash fastness and fade out after shampooing only 4 or 5 times. Furthermore, the range of shades obtained can be small;
oxidation dyeing or permanent dyeing uses the oxidative condensation of colorless or weakly colored molecules, known as oxidation bases, such as ortho- or para-phenylenediamines, ortho- or para-aminophenols or heterocyclic compounds in the presence of an oxidizing agent. This reaction can lead to the formation of colored polymer compounds in the keratin fibers. One advantage of oxidation dyeing lies in the longevity of the colorations obtained, for example, in the fastness to washing and to external agents, such as light, bad weather, permanent waving, perspiration and rubbing, and also in the production of a wide range of shades. However, the chemical dyeing conditions, such as the pH and use of an oxidizing medium, can result in the degradation of the keratin fibers. Moreover, this mode of dyeing may require relatively long leave-in times.

It is a known practice to use semiconductive luminescent inorganic nanoparticles, for example, comprising cadmium selenide or cadmium sulphide, for biological labeling of cells, such as in U.S. Pat. No. 5,990,479.

Disclosed herein is a method that provides novel dye compositions for dyeing keratin fibers, which do not have the drawbacks of those of the prior art. For example, the method, as disclosed herein, provides a novel dye system that can simultaneously have the advantages of fastness, such as with respect to repeated washings, gentleness on hair fibers, while allowing a wide variety of shades to be obtained.

Further disclosed herein is a method and composition comprising luminescent semiconductive nanoparticles capable of emitting, under the action of a light excitation, radiation with a wavelength ranging from 400 nm to 700 nm.

The luminescent semiconductive nanoparticles, as disclosed herein, make it possible to obtain, for example, in the field of dyeing of keratin materials, fast dyeing or optical lightening. For instance, the fast dyeing or optical lightening is obtained without degrading keratin fibers, such as human keratin fibers, such as hair.

As used herein, the expression “dyeing or optical lightening” means a visual dyeing or lightening effect on naturally or artificially colored keratin fibers, without using compounds that destroy the natural or artificial colored pigments present in the keratin fibers.

The luminescent semiconductive nanoparticles have, for example, the feature of having much narrower color emission spectra than most of the organic dyes or pigments used in hair dyeing. Purer colorations can thus be obtained.

Furthermore, the color emitted by these luminescent semiconductive nanoparticles varies as a function of their diameter. Thus, very varied ranges of colors may be obtained by using in the compositions one or more sizes of nanoparticles. The luminescent semiconductive nanoparticles also have, for example, the feature of emitting very strong colors.

According to one aspect of the disclosure, the luminescent semiconductive nanoparticles may comprise at least one metal chosen from Zn, Cd, Hg and at least one metal chosen from S, Se and Te. For example, the nanoparticles can comprise cadmium selenide or cadmium sulphide.

In the luminescent semiconductive nanoparticles, as disclosed herein, the metals present may be uniformly distributed. The luminescent semiconductive nanoparticles may also comprise a core comprising at least one metal, and at least one shell covering the core, wherein the shell comprises at least one metal other than those of which are present in the core. For example, the luminescent semiconductive nanoparticles comprise a core comprising at least one metal, and at least one shell covering this core, the shell comprising at least one metal other than those of which the core is composed. These nanoparticles are known in the literature as core/shell nanoparticles.

For example, according to this disclosure, the luminescent semiconductive nanoparticles may have a cadmium selenide core covered with a zinc sulphide shell.

The luminescent semiconductive nanoparticles may also be covered with at least one additional organic and/or inorganic shell, which, for example, can have affinity for the hair. Non-limiting examples of organic shells that may be mentioned include shells obtained from polyethylene glycol, polyurethane, dextran, polyacrylic, polyvinylpyrrolidone and polyvinylcaprolactone, and mixtures of these materials.

Examples of inorganic shells that may be mentioned include the shells obtained from alumina, silica and clay, and mixture of these materials.

The shells may be obtained via a sol-gel process using organosilane. Further, the shells, which are obtained by encapsulating nanoparticles, may be produced by various processes, such as controlled precipitation, phase separation, emulsion polymerization, interface polycondensation or in-situ polycondensation.

For further details, such encapsulation processes are described in “Microencapsulation Methods and Industrial Applications” (ISBN 0-8247-9703-5).

The encapsulated nanoparticle may be formed by any inorganic compound, for example, by metal oxides or organometallic polymers and further, for example, by metal oxides or organometallic polymers obtained via a sol-gel process, such as metal oxides or organometallic polymers synthesized by polycondensation of only one or of a mixture of simple or mixed alkoxy of silicon, aluminium, boron, lithium, magnesium, sodium, titanium and/or zirconium. For further details regarding the nature of the precursors and the reaction mechanisms, reference may be made to the book “Sol Gel Science” published by C. J. Brinker and G. W. Scherer published by Academic Press (ISBN 0-12-134970-5).

These additional layers may be covalently grafted or may be adsorbed onto the surface of the luminescent semiconductive nanoparticles.

According to one aspect of the disclosure, the luminescent semiconductive nanoparticles may be incorporated into polymer microbeads, wherein the polymer may possibly be chosen from hydrophilic, hydrophobic, amphiphilic, ionic and nonionic polymers. Polymers that may be mentioned include polystyrenes manufactured by the processes described in “Quantum-dot-tagged microbeads for multiplexed optical coding of biomolecules”, Mingyong Han, Nature Biotechnology Vol. 19, pp. 631-635, July 2001.

The luminescent semiconductive nanoparticles, as disclosed herein, may have a diameter ranging from 1 nm to 100 nm and, for example, from 1 nm to 50 nm. In one aspect, the nanoparticles have a diameter ranging from 1 nm to 20 nm.

Generally, luminescent semiconductive nanoparticles are known in the literature. For example, these nanoparticles may be manufactured according to the processes described, for example, in U.S. Pat. Nos. 6,225,198 or 5,990,479, which, are herein incorporated by reference, and also in the following publications: Dabboussi B. O. et al. “(CdSe)ZnS core-shell quantum dots: synthesis and characterization of a size series of highly luminescent nanocrystallites” Journal of Physical Chemistry B, Vol.101, 1997, pp. 9463-9475, and Peng, Xiaogang et al. “Epitaxial growth of highly luminescent CdSe/CdS core/shell nanocrystals with photostability and electronic accessibility” Journal of the American Chemical Society, Vol.119, No. 30, pp. 7019-7029. The luminescent semiconductive nanoparticles, disclosed herein, may also be known as “quantum dots”.

Non-limiting examples that may be mentioned include the following nanoparticles:

| Type of | | | Solution |
|---|---|---|---|
| nanoparticles | Size | Colors | concentration |
| CdSe | 2.2 nm | Green | 0.5 mg/ml |
| CdSe | 3.4 nm | Yellow | 0.5 mg/ml |
| CdSe | 4.0 nm | Orange | 0.5 mg/ml |
| CdSe | 4.7 nm | Orange-red | 0.5 mg/mI |
| CdSe | 5.6 nm | Red | 0.5 mg/ml |
| CdSe/ZnS | 4.3 nm | Green | 0.5 mg/ml |
| CdSe/ZnS | 4.8 nm | Green-yellow | 0.5 mg/ml |
| CdSe/ZnS | 5.4 nm | Yellow | 0.5 mg/ml |
| CdSe/ZnS | 6.3 nm | Orange | 0.5 mg/ml |
| CdSe/ZnS | 7.2 nm | Red | 0.5 mg/ml |

The nanoparticles can be supplied by the company Evident Technologies. The CdSe nanoparticles are uniform nanoparticles comprising only CdSe. The CdSe/ZnS nanoparticles have core/shell structures with a CdSe “core” and a ZnS “shell”.

According to one aspect of the disclosure, the luminescent semiconductive nanoparticles may be used in the dyeing of keratin materials, for example, keratin fibers, such as hair.

Disclosed herein is a composition for dyeing keratin materials, which comprises at least the luminescent semiconductive nanoparticles described above, in a suitable cosmetic medium.

The composition, as disclosed herein, can, for example, be intended for dyeing the hair. For instance, the composition may be in a form chosen from dyes, shampoos, conditioners, lacquers and hairsetting compositions. A person of ordinary skill in the art should define, without difficulty, from his or her general knowledge, the composition of the medium as a function of the nature of the dye composition.

For example, according to one aspect of the disclosure, the composition, disclosed herein, is a dye composition for dyeing keratin fibers, comprising, in a medium that is suitable for dyeing, nanoparticles as defined above.

The medium that is suitable for dyeing, also known as the dye support, generally comprises water or a mixture of water and at least one organic solvent to dissolve the compounds that would not be sufficiently soluble in water. Non-limiting examples of organic solvents that may be mentioned include C₁-C₄ lower alkanols, such as ethanol and isopropanol; polyols and polyol ethers, such as 2-butoxyethanol, propylene glycol, propylene glycol monomethyl ether, diethylene glycol monoethyl ether and monomethyl ether; and aromatic alcohols, for instance benzyl alcohol and phenoxyethanol, and mixtures thereof.

The solvents can be present, for example, in ,an amount ranging from 1% to 40% by weight, relative to the total weight of the dye composition, and further, for example, from 5% to 30% by weight, relative to the total weight of the dye composition.

The dye composition, as disclosed herein, can further comprise various adjuvants conventionally used in compositions for dyeing the hair, such as surfactants chosen from anionic, cationic, nonionic, amphoteric and zwitterionic surfactants; polymers chosen from anionic, cationic, nonionic, amphoteric and zwitterionic polymers; thickeners chosen from mineral and organic thickeners, and, for example, anionic, cationic, nonionic and amphoteric associative polymeric thickeners; antioxidants; penetration agents; sequestering agents; fragrances; buffers; dispersing agents; conditioning agents, such as volatile or non-volatile, and modified or unmodified silicones; film-forming agents; ceramides; preserving agents; and opacifiers.

The above adjuvants are each generally present in an amount ranging from 0.01% to 20% by weight, relative to the total weight of the composition.

The composition, disclosed herein, further comprises at least one surfactant, in addition to the luminescent semiconductive nanoparticles.

A person of ordinary skill in the art can take care to select these optional additional compounds such that the advantageous properties intrinsically associated with the oxidation dye composition, as disclosed herein, are not, or are not substantially, adversely affected by the additions envisaged.

The pH of the dye composition, disclosed herein, generally ranges from 3 to 12 and, for example, from 5 to 11. The pH may be adjusted to the desired value using acidifying or basifying agents generally used in the dyeing of keratin fibers, or alternatively using standard buffer systems.

Among the acidifying agents that may be used, non-limiting mention may be made of inorganic or organic acids, such as hydrochloric acid, orthophosphoric acid, sulphuric acid, carboxylic acids, such as acetic acid, tartaric acid, citric acid and lactic acid, and sulphonic acids.

Among the basifying agents that may be used, non-limiting mention may be made of aqueous ammonia, alkaline carbonates, alkanolamines, such as mono-, di- and triethanolamine and derivatives thereof, sodium hydroxide, potassium hydroxide and the compounds of formula (II) below: 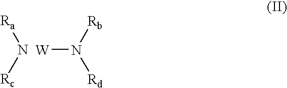
wherein W is a propylene residue optionally substituted with at least one group chosen from hydroxyl and C₁-C₄ alkyl groups; Rₐ, R_{b}, R_{c} and R_{d}, which may be identical or different, can be chosen from hydrogen, C₁-C₄ alkyl radicals and C₁-C₄ hydroxyalkyl radicals.

The dye composition, disclosed herein, may comprise various forms, such as liquids, creams and gels, or in any other form that is suitable for dyeing keratin fibers, such as human hair.

Further disclosed herein is a process for treating keratin fibers, for example, human keratin fibers such as hair, comprising applying to the fibers the composition disclosed herein.

For example, according to one aspect of the disclosure, the process of the invention is a process for dyeing keratin fibers. The composition of the invention may be applied to wet pr dry fibers. The application may be followed by a step of washing and/or rinsing the keratin fibers.

The example that follows serves to illustrate the invention without, however, being limiting in nature.

### EXAMPLE

1 ml of a solution of CdSe nanoparticles with a mean diameter of 4.0 nm was applied to a lock of 30 mg of natural hair comprised of 90% white hairs, and was left to act for five minutes.

The lock of the hair was drained and dried, and the color was observed in daylight. The lock was dyed orange.

What is claimed is:

1. A method for dyeing keratin fibers comprising, including in a composition, at least one luminescent semiconductive nanoparticle capable of emitting, under the action of a light excitation, radiation with a wavelength ranging from 400 nm to 700 nm.

2. The method according to claim 1, wherein the at least one luminescent semiconductive nanoparticle comprises at least one metal chosen from Zn, Cd, and Hg, and at least one metal chosen from S, Se and Te.

3. The method according to claim 1, wherein the at least one luminescent semiconductive nanoparticle is chosen from cadmium selenide and cadmium sulphide.

4. The method according to claim 1, wherein the at least one luminescent semiconductive nanoparticle comprises a core comprising at least one metal and at least one shell covering the core, wherein the shell comprises at least one metal other than the metal present in the core.

5. The method according to claim 4, wherein the at least one luminescent semiconductive nanoparticle comprises a cadmium selenide core covered with a Zn sulphide shell.

6. The method according to claim 1, wherein the at least one luminescent semiconductive nanoparticle can further be covered with at least one shell chosen from organic and inorganic shells.

7. The method according to claim 6, wherein the at least one organic shell comprises at least one organic material chosen from polyethylene glycol, polyurethane, dextran, polyacrylic, polyvinylpyrrolidone, and polyvinylcaprolactone.

8. The method according to claim 7, wherein the at least one organic shell comprises a mixture of dextran and polyethylene glycol.

9. The method according to claim 6, wherein the at least one inorganic shell comprises at least one inorganic material chosen from alumina, silica, and clay.

10. The method according to claim 9, wherein the at least one inorganic shell comprises a mixture of silica and alumina.

11. The method according to claim 1, wherein the at least one luminescent semiconductive nanoparticle can be incorporated into polymer microbeads.

12. The method according to claim 1, wherein the diameter of the at least one luminescent semiconductive nanoparticle ranges from 1 to 100 nm.

13. The method according to claim 12, wherein the diameter of the at least one luminescent semiconductive nanoparticle ranges from 1 to 50 nm.

14. The method according to claim 13, wherein the diameter of the at least one luminescent semiconductive nanoparticle ranges from 1 to 20 nm.

15. The method according to claim 1, wherein the keratin fibers are human keratin fibers.

16. The method according to claim 15, wherein the human keratin fibers are hair.

17. A dye composition comprising, in a medium that is suitable for dyeing, luminescent semiconductive nanoparticles capable of emitting, under the action of a light excitation, radiation with a wavelength ranging from 400 nm to 700 nm.

18. The composition according to claim 17, wherein the at least one luminescent semiconductive nanoparticle comprises at least one metal chosen from Zn, Cd, and Hg and at least one metal chosen from S, Se and Te.

19. The composition according to claim 17, wherein the at least one luminescent semiconductive nanoparticle is chosen from cadmium selenide and cadmium sulphide.

20. The composition according to claim 17, wherein the at least one luminescent semiconductive nanoparticle comprises a core comprising at least one metal and at least one shell covering the said core, wherein the shell comprises at least one metal other than the metal present in the core.

21. The composition according to claim 20, wherein the at least one luminescent semiconductive nanoparticle comprises a cadmium selenide core covered with a Zn sulphide shell.

22. The composition according to claim 17, wherein the at least one luminescent semiconductive nanoparticle can further be covered with at least one shell chosen from organic and inorganic shells.

23. The composition according to claim 22, wherein the at least one organic shell comprises at least one organic material chosen from polyethylene glycol, polyurethane, dextran, polyacrylic, polyvinylpyrrolidone, and polyvinylcaprolactone.

24. The composition according to claim 23, wherein the at least one organic shell comprises a mixture of dextran and polyethylene glycol.

25. The composition according to claim 22, wherein the at least one inorganic shell comprises at least one inorganic material chosen from alumina, silica, and clay.

26. The composition according to claim 25, wherein the at least one inorganic shell comprises a mixture of silica and alumina.

27. The composition according to claim 17, wherein the at least one luminescent semiconductive nanoparticle can be incorporated into polymer microbeads.

28. The composition according to claim 17, wherein the diameter of the at least one luminescent semiconductive nanoparticle ranges from 1 to 100 nm.

29. The composition according to claim 28, wherein the diameter of the at least one luminescent semiconductive nanoparticle ranges from 1 to 50 nm.

30. The composition according to claim 29, wherein the diameter of the at least one luminescent semiconductive nanoparticle ranges from 1 to 20 nm.

31. The composition according to claim 17, wherein the keratin fibers are human keratin fibers.

32. The composition according to claim 31, wherein the human keratin fibers are hair.

33. The composition according to claim 17, further comprising at least one surfactant.

34. The composition according to Claim 17, wherein the form of the composition is chosen from dyes, shampoos, conditioners, lacquers and hairsetting compositions.

35. A process for dyeing keratin fibers comprising applying to the fibers at least one dye composition comprising, in a medium that is suitable for dyeing, luminescent semiconductive nanoparticles capable of emitting, under the action of a light excitation, radiation with a wavelength ranging from 400 nm to 700 nm.

36. The process according to claim 35, wherein the keratin fibers are human keratin fibers.

37. The process according to claim 36, wherein the human keratin fibers are hair.
